(19) United States
(12) Patent Application Publication
(10) Pub. No.: US 2009/0059498 A1
(43) Pub. Date: Mar. 5, 2009

(54) Electronic appliance and method for manufacturing the same

(75) Inventors: Jeo Woo Jeong, Seoul (KR); Tae Sang Park, Seoul (KR); Young Jun Moon, Suwon-si (KR); Hark Byeong Park, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 12/155,751

(22) Filed: Jun. 9, 2008

(30) Foreign Application Priority Data
Sep. 3, 2007 (KR) 10-2007-0088988

(51) Int. Cl. H05K 5/02; G06F 1/16; H05K 5/00; H05K 7/00

(52) U.S. Cl. 361/681; 361/758

(57) ABSTRACT

An electronic appliance to achieve an increased rigidity thereof with a simplified manner without any change in design and configuration and a method for manufacturing the same. The electronic appliance includes a case defining the outer appearance of the electronic appliance, and a printed circuit board disposed in the case and having electronic elements mounted thereon. A resin is filled between the case and the printed circuit board.

### CROSS-REFERENCE TO RELATED APPLICATIONS

This application claims the benefit of Korean Patent Application No. 2007-0088988, filed on Sep. 13, 2007 in the Korean Intellectual Property Office, the disclosure of which is incorporated herein by reference.

### BACKGROUND

1. Field

The present invention relates to an electronic appliance having a printed circuit board and a method for manufacturing the same, and, more particularly, to an electronic appliance having a strength-reinforcing structure and a method for manufacturing the same.

2. Description of the Related Art

Electronic appliances include a printed circuit board (hereinafter, referred to as a “PCB”). In one exemplary configuration of general electronic appliances, a PCB, on which electronic elements, connectors, etc. are mounted, is fixed in upper and lower housings. A display panel, such as an LCD, etc., can be fixed on the PCB in various manners.

Nowadays, the electronic appliances are increasingly much thinner and lighter. In particular, the latest, newly-developed mobile products, such as a personal digital assistant (PDA) and a portable multimedia player (PMP), are gradually reduced in thickness for miniaturization of products. For this, the electronic elements and PCB within the electronic appliances are also becoming leaner.

However, the smaller the thickness of the electronic appliance and the thickness of the PCB and electronic elements within the electronic appliance, the greater the possibility of deformation of the housings and PCB, etc. by an external shock or load is. With the increase of deformation, a considerably increased stress is concentrated on the connectors between the housings, PCB, and electronic elements and the display panel such as an LCD, etc., thereby causing a high possibility of breakage of the electronic appliance, and consequently, the generation of defective products.

As a solution of the above described problem, it has been proposed, for example, to provide the housings with reinforcing members or brackets, etc. to prevent deformation of the PCB, or make the housings or PCB of highly rigid materials. However, since this solution requires to newly design and make housings and PCBs for new products, there are problems of extended manufacturing times and high manufacturing costs of the electronic appliance.

As another solution, Korean Patent Laid-open Publication No. 10-2006-0111404 discloses a method for manufacturing an electronic circuit device including a circuit board having circuits mounted thereon, terminals mounted on the circuit board and electrically connected thereto, and a casing made of a resin. The disclosed method includes: holding the circuit board in a cavity of a casing-forming die such that a surface of the circuit board comes into close contact with a wall surface of the forming die; filling the cavity with a resin; and hardening the resin in the cavity

The electronic circuit device manufactured by the disclosed invention of the above publication has the effect of preventing deformation of the circuit board or damage to electronic elements by virtue of the filled resin. However, since the case should be formed by injection molding after the circuit board having circuits is inserted into the forming die, the provision of the forming die is essential and the addition of injection molding results in increased manufacturing costs.

Further, when a display panel is mounted on the printed circuit board, it should be noted that the resin does not come into contact with the display panel. Therefore, the disclosed invention of the above publication has a difficulty to manufacture an electronic circuit device having a display panel.

### SUMMARY

Accordingly, it is an aspect of the invention to provide an electronic appliance and a method for manufacturing the same, which can increase the rigidity of a product by a simplified manner without any change in design and configuration.

Additional aspects and/or advantages of the invention will be set forth in part in the description which follows and, in part, will be apparent from the description, or may be learned by practice of the invention.

In accordance with one aspect of the invention, the above and/or other aspects can be achieved by the provision of an electronic appliance including: a case defining the outer appearance of the electronic appliance; and a printed circuit board disposed in the case and having electronic elements mounted thereon, wherein a resin is filled between the case and the printed circuit board.

The case may include a first case to cover one surface of the printed circuit board, and a second case to cover the other surface of the printed circuit board, and the resin may be filled in at least one of spaces between the printed circuit board and the first case and between the printed circuit board and the second case.

At least one of the printed circuit board and the case may include an injecting hole to inject the resin into a space between the case and the printed circuit board.

The resin may be epoxy resin.

In accordance with another aspect of the present invention, there is provided an electronic appliance including: a printed circuit board having electronic elements mounted thereon; a first case to cover one surface of the printed circuit board; and a second case to cover the other surface of the printed circuit board, wherein a resin is filled between one of the first and second cases and the printed circuit board.

The electronic elements may be mounted at one surface of the printed circuit board and a display is mounted at the other surface of the printed circuit board, and the resin may be filled between one surface of the printed circuit board and the first case.

The electronic appliance may further include: a sealing member to seal a gap between the printed circuit board and the first case, wherein the printed circuit board includes an injecting hole to inject the resin into the gap between the first case and the printed circuit board.

In accordance with a further aspect of the present invention, there is provided a method for manufacturing an electronic appliance including: a case defining the outer appearance of the electronic appliance; and a printed circuit board disposed in the case and having electronic elements mounted thereon, the method including: forming a cavity between the printed circuit board and the case by fixing the printed circuit board to the case; filling a resin into the cavity; and hardening the resin in the cavity.

The formation of the cavity may include: sealing a joint between the case and the printed circuit board.

The printed circuit board may include an injecting hole, and the filling of the resin is performed to fill the resin into the cavity through the injecting hole.

The electronic elements may be mounted at one surface of the printed circuit board and a display may be mounted at the other surface of the printed circuit board, and the filling of the resin may be performed to fill the resin into the cavity between the case and one surface of the printed circuit board at which the electronic elements are mounted.

In accordance with yet another aspect of the present invention, there is provided a method for manufacturing an electronic appliance including: first and second cases defining the outer appearance of the electronic appliance; and a printed circuit board disposed between the first and second cases and having electronic elements mounted thereon, the method including: forming a cavity between the printed circuit board and the first case by fixing one surface of the printed circuit board to the first case; filling a resin into the cavity; and fixing the second case to the other surface of the printed circuit board.

At least one of the printed circuit board and the case may include an injecting hole to inject the resin, and the resin is filled into the cavity through the injecting hole.

### BRIEF DESCRIPTION OF THE DRAWINGS

These and/or other aspects and advantages of the exemplary embodiments of the invention will become apparent and more readily appreciated from the following description of the embodiments, taken in conjunction with the accompanying drawings, of which:

FIG. 1 is a schematic sectional view showing an electronic appliance according to a first embodiment of the present invention;

FIG. 2, parts (a)-(d), are sectional views showing the sequence of a method for manufacturing the electronic appliance according to the first embodiment of the present invention;

FIG. 3 is a schematic sectional view showing an electronic appliance according to a second embodiment of the present invention;

FIG. 4, parts (a)-(d), are sectional views showing the sequence of a method for manufacturing the electronic appliance according to the second embodiment of the present invention;

FIG. 5 is a schematic sectional view showing an electronic appliance according to a third embodiment of the present invention;

FIG. 6, parts (a)-(c), are sectional views showing the sequence of a method for manufacturing the electronic appliance according to the third embodiment of the present invention.

### DETAILED DESCRIPTION OF THE EMBODIMENTS

Reference will now be made in detail to exemplary embodiments of the present invention, examples of which are illustrated in the accompanying drawings, wherein like reference numerals refer to like elements throughout. The embodiments are described below to explain the present invention by referring to the figures.

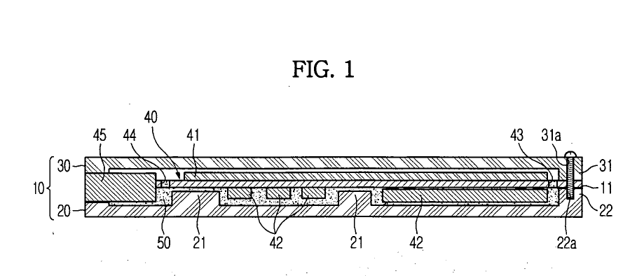

FIG. 1 is a schematic sectional view showing an electronic appliance according to a first embodiment of the present invention.

The electronic appliance according to the first embodiment of the present invention, as shown in FIG. 1, includes a case 10 to form the outer appearance of the electronic appliance, and a printed circuit board 40 (hereinafter, referred to as a “PCB”) installed at a fixed position in the case 10 and having electronic elements, etc. mounted thereon.

The case 10 includes a first case 20 defining the lower part of the electronic appliance, and a second case 30 disposed on and coupled with the first case 20 to complete the outer appearance of the electronic appliance.

The first case 20 has reinforcing protrusions 21 therein to reinforce the strength of the electronic appliance. Positions of the reinforcing protrusions 21 are design options, and the reinforcing protrusions 21 can be selectively formed at positions requiring a reinforced strength.

The first case 20 further has a first coupling portion 22 protruding upward from a partial rim thereof, to allow the PCB 40 to be put on the first case 20.

The first coupling portion 22 has a first screw hole 22a for screw-fastening with the second case 30.

The second case 30 is coupled to the top of the first case 20 on which the PCB 40 was mounted, to complete the outer appearance of the electronic appliance. The first case 20 has a second coupling portion 31 corresponding to the first coupling portion 22. Also, the second coupling portion 31 has a second screw hole 31a corresponding to the first screw hole 22a, for the coupling of the first and second cases 20 and 30.

The second case 30 may be formed of a transparent injection-molded article, to allow an image, etc. of a display 41 mounted on the PCB 40 to be seen from the outside. Alternatively, only a portion of the second case 30 corresponding to the display 41 may be formed of a transparent material, and the remaining portion of the second case 30 may be formed with various colors of opaque materials suitable to provide a user with aesthetic appreciation.

The PCB 40 is fixed between the first case 20 and the second case 30. Now, the manufacture of the PCB 40 will be described in brief.

To manufacture the PCB 40, after a copper foil is attached to a thin substrate made of epoxy resin or bakelite resin as an insulator, a resist is printed on a circuit wiring where it is desired to leave the copper foil. Then, if the printed substrate is immersed in an etching solution capable of melting copper, the copper foil, which is not covered with the resist, is melted. Thereafter, if the resist is removed, the remaining copper foil defines a desired electric conductor wiring pattern, to complete the PCB 40.

In this case, note that the PCB 40 can be formed by use of other kinds of resins or ceramics, other than the epoxy resin or bakelite resin.

The display 41 is provided at an upper surface of the PCB 40. The display 41 is a flat panel display such as a liquid crystal display. In the case of the liquid crystal display, an electric field is applied to liquid crystals, having an anisotropic dielectric constant, injected between two substrates, and the transmissivity of light from an external light source to the substrates can be adjusted by adjusting the strength of the electric field. In this way, the liquid crystal display can obtain a desired image signal.

Although the display 41 according to the present invention can be realized by the liquid crystal display, more particularly, a TFT-LCD using a thin-film transistor as a switching device, other various kinds of flat panel displays easy to carry can be used.

The display 41 using the liquid crystal display is well known in the art, and a detailed description thereof will be omitted.

In addition to the display 41, although not shown in the drawing, various electronic elements can be mounted at the upper surface of the PCB 40.

Also, a plurality of electronic elements 42 are mounted at a lower surface of the PCB 40.

The electronic elements 42 include a plurality of integrated circuits such as a ball grid array (BGA), chip scale package (CSP), and land grid array (LGA), and a plurality of passive elements such as a condenser. The electronic elements 42 further include a controller (not shown) to drive the display 41.

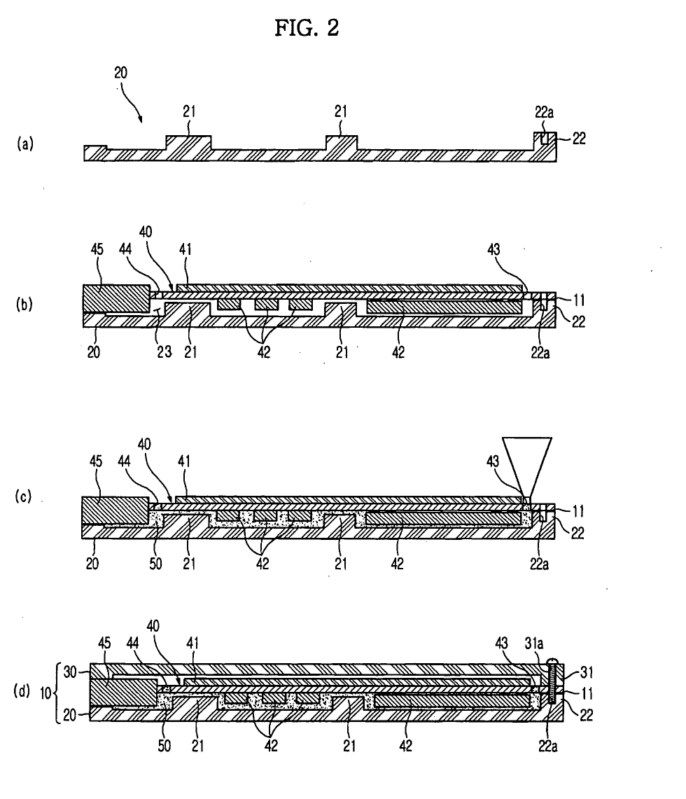

The PCB 40 has an injecting hole 43 and an air discharge hole 44, to inject a resin 50, which will be described hereinafter, into a cavity 23 between the PCB 40 and the first case 20 (See FIG. 2, part (b)). If the resin 50 is injected through the injecting hole 43, air inside the cavity 23 is discharged through the air discharge hole 44, thereby allowing the resin 50 to be filled between the PCB 40 and the first case 20.

Positions and the number of the injecting hole and the air discharge hole can be determined appropriately, to ensure smooth flow of the resin.

A sealing member 11 is used to seal a gap between the PCB 40 and the first coupling portion 22 of the first case 20, to prevent the resin 50 from leaking through the gap between the PCB 40 and the first case 20 during the filling of the resin 50. In this case, the sealing member 11 may be an adhesive, double-faced tape, or the like. Note that other various kinds of structures to assure a strong attachment between the PCB and the first case can be used as the sealing member.

A connector 45 is provided at one side of the PCB 40 and used to be detachably connected to a plug (not shown).

Once the PCB 40 is fixed to come into strong contact with the first coupling portion 22 of the first case 20 by the sealing member 11, the resin 50 is injected, through the injecting hole 43 perforated in the PCB 40, into the cavity 23 between the lower surface of the PCB 40 and the first case 20. Since the resin 50 is initially in a liquid state having a predetermined viscosity, it can be easily filled in the cavity 23. In this case, the air discharge hole 44 perforated in the PCB 40 ensures the smooth injection of the resin 50.

One example of the resin 50 includes epoxy resin as a thermosetting resin. The epoxy resin has superior heat-resistance and high mechanical strength and can improve the strength and reliability of the electronic appliance. Note that the resin is not limited to the epoxy resin, and other kinds of thermosetting resins may be used.

As the injected resin 50 is hardened after the lapse of a predetermined time, the PCB 40 and the first case 20 can be integrated with each other by the resin 50 filled in the cavity 23, thereby maintaining an improved strength as compared to the prior art.

Accordingly, even where the PCB 40 and the first case 20 are made of thin soft materials, they can acquire a high strength owing to the resin 50 injected and hardened between the PCB 40 and the first case 20.

Further, since the resin 50 can be injected into the space between the PCB 40 and the first case 20 through the injecting hole 43 perforated in the PCB 40 without the manufacture of a separate mold, the manufacturing costs of the electronic appliance can be reduced.

Hereinafter, a method for manufacturing the electronic appliance according to the first embodiment of the present invention will be described.

FIG. 2, parts (a)-(d), are sectional views illustrating the process sequence of the electronic appliance according to the first embodiment of the present invention.

Referring to FIG. 2, part (a), if the first case is prepared, the PCB 40 is mounted on the first coupling portion 22 protruding from the first case 20. The PCB 40 is provided at the upper surface thereof with the display 41 and at the lower surface thereof with the electronic elements 42. The sealing member 11 is inserted between the first coupling portion 22 of the first case 20 and a corresponding rim of the PCB 40, to eliminate the gap between the rim of the PCB 40 and the first coupling portion 22 of the first case 20.

Subsequently, the resin 50 is injected into the space between the first case 20 and the PCB 40 through the injecting hole 43 perforated in the PCB 40. The resin 50 is initially in a melted liquid state, and can be injected through the injecting hole 43 as shown in FIG. 2, part (c), to be filled in the cavity 23 between the first case 20 and the PCB 40. If the resin 50 is dispersed throughout the cavity 23 as the air inside the cavity 23 is discharged through the air discharge hole 44, the injection of the resin 50 is stopped, and the filling operation is completed.

The resin 50 filled in the cavity 23 is hardened, to integrate the first case 20 and the PCB 40 with each other.

Then, to cover the upper surface of the PCB 40, as shown in FIG. 2, part (d), the second case 30 is coupled to the top of the first case 20, on which the PCB 40 was mounted. As the first and second cases 20 and 30 are coupled with each other by means of screws, etc., the manufacture of the electronic appliance according to the first embodiment of the present invention is completed.

Next, an electronic appliance according to a second embodiment of the present invention will be described with reference to the accompanying drawing.

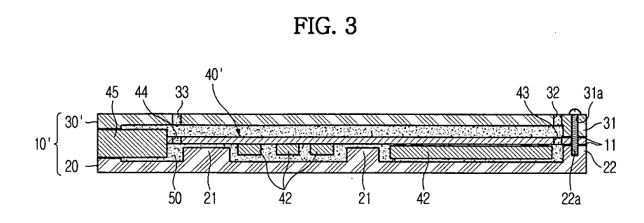

FIG. 3 is a schematic sectional view showing an electronic appliance according to a second embodiment of the present invention.

Since the second embodiment of the present invention has a configuration similar to that of the previously described first embodiment, the same constituent elements as those of the first embodiment are designated by the same reference numerals, and a description thereof will be omitted.

The electronic appliance according to the second embodiment of the present invention includes a case 10′ defining the outer appearance of the electronic appliance, and a PCB 40′ fixedly mounted in the case 10′ and having electronic elements, etc mounted thereon.

The case 10′ includes the first case 20, on which the PCB 40′ is mounted, and a second case 30′ coupled to the top of the first case 20 to complete the outer appearance of the electronic appliance. The second case 30′ has the second coupling portion 31 corresponding to the first coupling portion 22 of the first case 20. Also, the second coupling portion 31 has the second screw hole 31a corresponding to the first screw hole 22a, for the coupling of the first and second cases 20 and 30′.

The second case 30′ has an injecting hole 32 and an air discharge hole 33 to inject the resin 50 into the coupled first and second cases 20 and 30′. Accordingly, if the resin 50 is injected through the injecting hole 32, air inside the cases 20 and 30′ is discharged through the air discharge hole 33, thereby ensuring smooth filling of the resin 50.

Positions and the number of the injecting hole and the air discharge hole can be determined appropriately to ensure the smooth flow of the resin.

The PCB 40′ of the second embodiment, differently from the first embodiment of the present invention, has no display, and the plurality of electronic elements 42 are mounted at both upper and lower surfaces of the PCB 40′.

The PCB 40′ has the injecting hole 43 and an air discharge hole 44, to allow the resin 50, which was injected through the injecting hole 32 of the second case 30′, to be injected into a first cavity 12 between the PCB 40′ and the first case 20. The injecting hole 43 and the air discharge hole 44 of the PCB 40′ may be formed at positions corresponding to the injecting hole 32 and the air discharge hole 33 of the second case 30′, or may be formed at other appropriate positions to ensure the smooth flow of the resin 50.

The sealing member 11 is used to seal gaps between the lower surface of the PCB 40′ and the first coupling portion 22 of the first case 20 and between the upper surface of the PCB 40′ and the second coupling portion 31 of the second case 30′, to prevent the resin 50 from leaking through the gaps between the PCB 40′ and the first and second cases 20 and 30 during the filling of the resin 50.

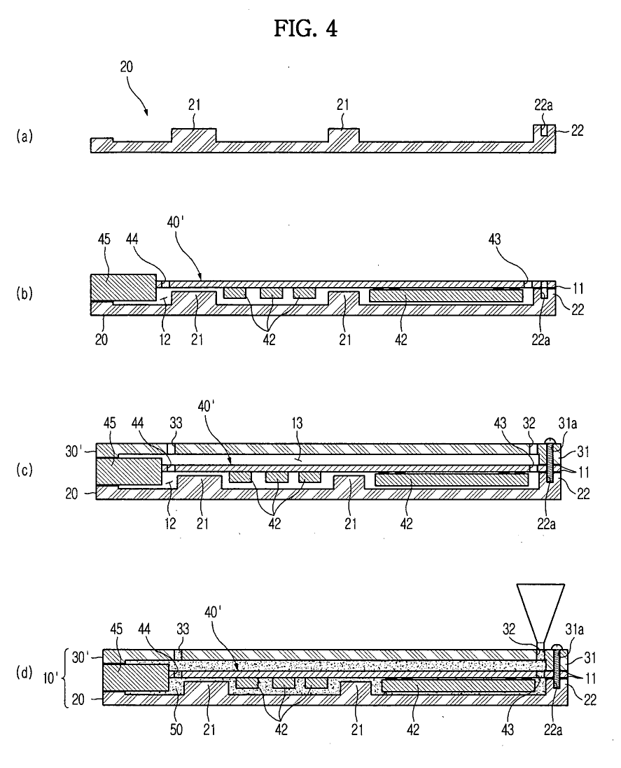

Accordingly, after the lower surface of the PCB 40′ and the first case 20 are attached to each other by use of the sealing member 11, and the second case 30′ and the upper surface of the PCB 40′ are attached to each other by use of the sealing member 11, the first and second cases 20 and 30′ can be firmly coupled with each other by use of screws. Subsequently, if the resin 50 is injected into the electronic appliance through the injecting hole 32 of the second case 30′, the air inside the electronic appliance is discharged through the air discharge hole 33, thereby allowing the resin 50 to be filled in both the first cavity 12 between the PCB 40′ and the first case 20 and a second cavity 13 between the PCB 40′ and the second case 30′ (See FIG. 4, parts (a)-(d)).

As the injected resin 50 is hardened after the lapse of a predetermined time, the PCB 40′ and the case 10′ can be integrated with each other by the resin 50 filled in the first and second cavities 12 and 13, thereby maintaining an improved strength as compared to the prior art.

Accordingly, the above described second embodiment enables the resin to be filled in the electronic appliance without the manufacture of a separate mold in the same manner as the first embodiment. Further, the resin can be filled in the overall interior of the electronic appliance because the PCB 40′ has no display. Therefore, the present embodiment has the effect of further improving the strength of the electronic appliance even when the electronic appliance has a thinner thickness than that of the first embodiment.

Hereinafter, a method for manufacturing the electronic appliance according to the second embodiment of the present invention will be described.

FIG. 4, parts (a)-(d), are sectional views illustrating the process sequence of the electronic appliance according to the second embodiment of the present invention.

If the first case 20 is prepared as shown in FIG. 4, part (a), the PCB 40′ is disposed on the first coupling portion 22 protruding from the first case 20. In this case, the sealing member 11 is inserted between the first coupling portion 22 of the first case 20 and a corresponding rim of the PCB 40′ as shown in FIG. 4, part (b), to eliminate the gap between the rim of the PCB 40′ and the first coupling portion 22 of the first case 20.

Subsequently, the sealing member 11 is also used to fix the second case 30′ on the PCB 40′ which was coupled with the first case 20, to cover the upper surface of the PCB 40′ as shown in FIG. 4, part (c). The first and second cases 20 and 30′ are coupled with each other by use of screws, etc., such that the first and second cavities 12 and 13 within the electronic appliance are separated from each other.

Thereafter, as shown in FIG. 4, part (c), the resin 50 is injected into the first and second cavities 12 and 13 through the injecting hole 32 perforated in the second case 30′. In this case, if the resin 50 is dispersed throughout the first and second cavities 12 and 13 as the air inside the cavities 12 and 13 is discharged through the air discharge hole 33, the injection of the resin is stopped, and the filling operation is completed. The resin 50 filled in the first and second cavities 12 and 13 is hardened, to integrate the case 10′ and the PCB 40′ with each other.

With the above described method, the manufacture of the electronic appliance according to the second embodiment of the present invention is completed.

Next, an electronic appliance according to a third embodiment of the present invention will be described with reference to the accompanying drawing.

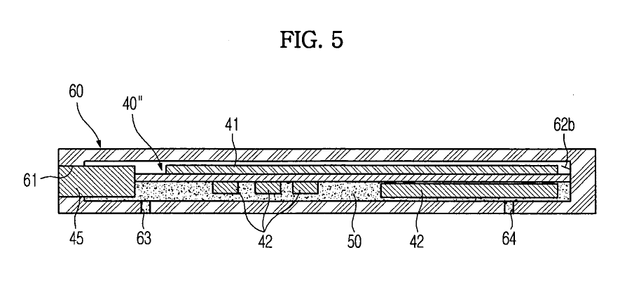

FIG. 5 is a schematic sectional view showing an electronic appliance according to a third embodiment of the present invention.

The electronic appliance according to the third embodiment of the present invention, as shown in FIG. 5, includes a case 60 defining the outer appearance of the electronic appliance, and a PCB 40” fixedly mounted in the case 60 and having the electronic elements 42, etc. mounted thereon.

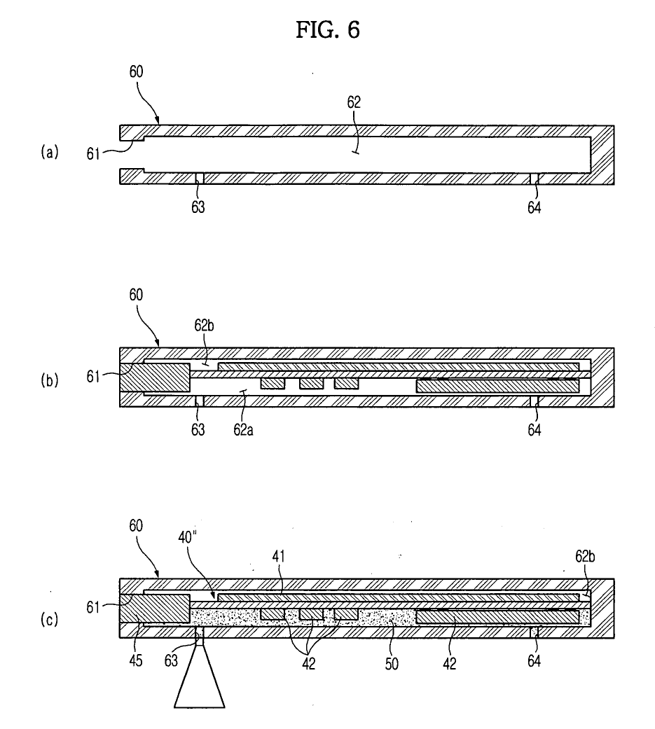

The case 60 has an opening 61 perforated through one side thereof, and a cavity 62 defined therein for the installation of the PCB 40″ (See FIG. 6, part (a)).

A pair of guides (not shown) are provided in the case 60, to guide the insertion of the PCB 40″.

Similar to the PCB 40 of the first embodiment, the PCB 40″ is provided at an upper surface thereof with the display 41 and at a lower surface thereof with the plurality of electronic elements 42.

The PCB 40″ is inserted into the case 60 while being guided by the guides (not shown) of the case 60. The PCB 40″ divides the interior space of the case 60 into first and second cavities 62a and 62b (See FIG. 6, part (b)).

The case 60 is perforated, in the bottom thereof, with an injecting hole 63 and an air discharge hole 64, to inject the resin 50 into the first cavity 62a divided in the case 60 by the PCB 40″. If the resin 50 is injected through the injecting hole 63, air inside the first cavity 62a is discharged through the air discharge hole 64, thereby allowing the resin 50 to be filled in the first cavity 62a (See FIG. 6, part (c)).

An upper portion of the case 60 may be formed of a transparent injection-molded article, to allow an image, etc. of the display 41 mounted on the PCB 40″ to be seen from the outside. Alternatively, only a portion of the case 60 corresponding to the display 41 may be formed of a transparent material.

An interface between the PCB 40″ and the case 60 is sealed by use of a sealing member (not shown), to prevent the resin 50 from leaking into the second cavity 62b while the resin is filled the overall first cavity 62a.

If the resin 50 is injected into the first cavity 62a through the injecting hole 63 in the sealed state of the PCB 40″ and the case 60, the resin 50 can be easily filled in the space defined between the first case 60 and the PCB 40″. In this case, since the case 60 has the air discharge hole 64, the smooth injection of the resin 50 can be acquired.

Accordingly, even where the PCB 40″ and the case 60 are made of thin soft materials, they can acquire a high strength as the resin 50 is injected into and hardened in the first cavity 62a.

Next, a method for manufacturing the electronic appliance according to the third embodiment of the present invention will be described.

FIG. 6, parts (a)-(c) are sectional views illustrating the process sequence of the electronic appliance according to the third embodiment of the present invention.

If the case 60 is prepared as shown in FIG. 6, part (a), the PCB 40″ is slidably inserted into the case 60 through the opening 61 of the case 60. In this case, to prevent the resin 50 from leaking into the second cavity 62b while the resin 50 is filled in the first cavity 62a, the interface between the PCB 40″ and the case 60 is sealed by use of the sealing member (not shown) to eliminate a gap in the interface between the case 60 and the PCB 40″.

Subsequently, as shown in FIG. 6, part (c), the resin 50 is injected into the first cavity 62a through the injecting hole 63 perforated in the case 60.

The resin 60 is initially in a melted liquid state and can be injected through the injecting hole 63 to be filled in the first cavity 62a. If the resin 50 is dispersed throughout the first cavity 62a as the air inside the first cavity 62a is discharged through the air discharge hole 64, the injection of the resin is stopped, and the filling operation is completed.

The resin 50 filled in the first cavity 62a is hardened, to integrate the case 60 and the PCB 40″ with each other. In this way, if the hardening operation is finished, the manufacture of the electronic appliance is completed.

As a result of manufacturing the electronic appliance by filling the resin 50 in the first cavity 62a after inserting the PCB 40″ into the case 60, the present embodiment has the effect of simplifying the overall manufacturing process and achieving a desired rigidity with a thin thickness of the electronic appliance.

As apparent from the above description, the present invention provides an electronic appliance in which a resin is injected into and hardened in a space between a PCB and a case, thereby providing the electronic appliance with a high strength.

Furthermore, since the resin can be injected into a cavity of the case through an injecting hole perforated in the case or PCB without the manufacture of a separate mold, the overall manufacturing process of the electronic appliance can be simplified, resulting in reduced manufacturing costs.

Although embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An electronic appliance comprising:
a case defining the outer appearance of the electronic appliance; and
a printed circuit board disposed in the case and having electronic elements mounted thereon,
wherein a resin is filled between the case and the printed circuit board.

2. The electronic appliance according to claim 1, wherein
the case comprises a first case to cover one surface of the printed circuit board, and a second case to cover the other surface of the printed circuit board, and
the resin is filled in at least one of spaces between the printed circuit board and the first case and between the printed circuit board and the second case.

3. The electronic appliance according to claim 1, wherein at least one of the printed circuit board and the case comprises an injecting hole to inject the resin into a space between the case and the printed circuit board.

4. The electronic appliance according to claim 1, wherein the resin is epoxy resin.

5. An electronic appliance comprising:
a printed circuit board having electronic elements mounted thereon;
a first case to cover one surface of the printed circuit board; and
a second case to cover the other surface of the printed circuit board.
wherein a resin is filled between one of the first and second cases and the printed circuit board.

6. The electronic appliance according to claim 5, wherein
the electronic elements are mounted at one surface of the printed circuit board and a display is mounted at the other surface of the printed circuit board, and
the resin is filled between one surface of the printed circuit board and the first case.

7. The electronic appliance according to claim 5, further comprising a sealing member to seal a gap between the printed circuit board and the first case,
wherein the printed circuit board comprises an injecting hole to inject the resin into the gap between the first case and the printed circuit board.

8. A method for manufacturing an electronic appliance having a case defining the outer appearance of the electronic appliance, a printed circuit board disposed in the case, and electronic elements mounted on the printed circuit board, the method comprising:
forming a cavity between the printed circuit board and the case by fixing the printed circuit board to the case;
filling a resin into the cavity; and
hardening the resin in the cavity.

9. The method according to claim 8, wherein the formation of the cavity comprises: sealing a joint between the case and the printed circuit board.

10. The method according to claim 8, wherein
the printed circuit board comprises an injecting hole, and
the filling of the resin is performed to fill the resin into the cavity through the injecting hole.

11. The method according to claim 8, wherein
the electronic elements are mounted at one surface of the printed circuit board and a display is mounted at the other surface of the printed circuit board, and
the filling of the resin is performed to fill the resin into the cavity between the case and one surface of the printed circuit board at which the electronic elements are mounted.

12. A method for manufacturing an electronic appliance having first and second cases defining the outer appearance of the electronic appliance, a printed circuit board disposed between the first and second cases and electronic elements mounted on the printed circuit board, the method comprising:
forming a cavity between the printed circuit board and the first case by fixing one surface of the printed circuit board to the first case;
filling a resin into the cavity; and
fixing the second case to the other surface of the printed circuit board.

13. The method according to claim 12, wherein at least one of the printed circuit board and the case comprises an injecting hole to inject the resin, and the resin is filled into the cavity through the injecting hole.

14. The electronic appliance according to claim 3, wherein at least one of the printed circuit board and the case further comprises an air discharge hole.

15. The electronic appliance according to claim 7, wherein the printed circuit board further comprises an air discharge hole.
